(19) United States
(12) Patent Application Publication
(10) Pub. No.: US 2021/0144319 A1
(43) Pub. Date: May 13, 2021

(54) SYSTEMS AND METHODS FOR GENERATING HIGH DYNAMIC RANGE IMAGES

(71) Applicant: SEMICONDUCTOR COMPONENTS INDUSTRIES, LLC, Phoenix, AZ (US)

(72) Inventors: Manuel H. INNOCENT, Wezemaal (BE); Tomas GEURTS, Haasrode (BE)

(73) Assignee: SEMICONDUCTOR COMPONENTS INDUSTRIES, LLC, Phoenix, AZ (US)

(21) Appl. No.: 16/677,892

(22) Filed: Nov. 8, 2019

(51) Int. Cl. H04N 5/355; H04N 5/235; H04N 5/378; H01L 27/146

(52) U.S. Cl. CPC H04N 5/3559; H04N 5/2355; H04N 5/378; H01L 27/1463; H01L 27/14612; H01L 27/14607; H01L 27/14643

(57) ABSTRACT

An imaging system may include an array of image pixels, each image pixel including two photodiodes. A first photodiode may surround a second photodiode. Each image pixel may include two low gain capacitors. A first low gain capacitor may be coupled to a floating diffusion region connected to the two photodiodes via respective transistors. A second low gain capacitor may be coupled to the second photodiode directly or via an interposing transistor. Charge generated by the first photodiode may be separated into an overflow portion stored at the first low gain capacitor and a remaining portion stored at the first photodiode. The overflow charge portion may be used to generated a first signal. The remaining charge portion (along with other charge generated by the first photodiode) may be used to generate a second signal. The charge generated by the second photodiode may be used to generated a third signal.

### BACKGROUND

This relates generally to imaging devices, and more particularly, to imaging devices for generating high dynamic range images.

Image sensors are commonly used in electronic devices such as cellular telephones, cameras, and computers to capture images. In a typical arrangement, an electronic device is provided with an array of image pixels arranged in pixel rows and pixel columns.

In many applications, such as automotive applications, a high dynamic range operation of the image pixels without introducing motion artifacts is an important requirement. This typically requires that the image pixels exhibit a high dynamic range using only a single integration time (per shutter and readout cycle). It would be therefore desirable to increase the dynamic range of the pixel while optimizing for signal-to-noise ratio (SNR).

It is within this context that the embodiments herein arise.

### BRIEF DESCRIPTION OF THE DRAWINGS

FIG. 1 is a diagram of an illustrative imaging system or device having an image sensor and processing circuitry in accordance with some embodiments.

FIG. 2 is a diagram of an illustrative image sensor having a pixel array and associated readout and control circuitry in accordance with some embodiments.

FIG. 3 is a diagram of an illustrative image pixel having two low gain capacitors in accordance with some embodiments.

FIG. 4 is a diagram of an illustrative image pixel having two low gain capacitors with an indirect photosensitive element to floating diffusion region connection in accordance with some embodiments.

FIG. 5 is a diagram of an illustrative image pixel having two low gain capacitors, one of which is connected to a photosensitive element using a transistor, in accordance with some embodiments.

FIG. 6 is a diagram of an illustrative image pixel having two low gain capacitors, one of which is connected to a photosensitive element using a transistor, and with an indirect photosensitive element to floating diffusion region connection in accordance with some embodiments.

FIG. 7 is a top view of an illustrative image pixel having inner and outer photosensitive elements in accordance with some embodiments.

FIG. 8 is a cross-sectional view of an illustrative image pixel having a buried photosensitive element in accordance with some embodiments.

FIG. 9 is an illustrative timing diagram for operating an image pixel such as the image pixel shown in FIG. 3 or FIG. 4 in accordance with some embodiments.

FIG. 10 is another illustrative timing diagram for operating an image pixel such as the image pixel shown in FIG. 3 or FIG. 4 in accordance with some embodiments.

FIG. 11 is a diagram of an illustrative image pixel with an additional anti-blooming transistor in accordance with some embodiments.

FIG. 12 is a diagram of an illustrative image pixel having parallel reset and dual conversion gain paths to a floating diffusion region in accordance with some embodiments.

### DETAILED DESCRIPTION

Electronic devices such as digital cameras, computers, cellular telephones, and other electronic devices may include image sensors that gather incoming light to capture an image. The image sensors may include arrays of image pixels. The pixels in the image sensors may include photosensitive elements such as photodiodes that convert the incoming light into sets of electric charge (e.g., corresponding to image signals). Image sensors may have any number of pixels (e.g., hundreds or thousands or more). A typical image sensor may, for example, have hundreds of thousands or millions of pixels (e.g., megapixels). Image sensors may include control circuitry such as circuitry for operating the image pixels and readout circuitry for reading out image signals corresponding to the electric charge generated by the photosensitive elements.

FIG. 1 is a diagram of an illustrative imaging system such as an electronic device that uses an image sensor to capture images. Electronic device 10 of FIG. 1 may be a portable electronic device such as a camera, a cellular telephone, a tablet computer, a webcam, a video camera, a video surveillance system, an automotive imaging system, a video gaming system with imaging capabilities, or any other desired imaging system or device that captures image data. Camera module 12 (sometimes referred to as an imaging module) may be used to convert incoming light into (digital) image data. Camera module 12 may include one or more lenses 14 and one or more corresponding image sensors 16. Lenses 14 may include fixed and/or adjustable lenses and may include microlenses formed on an imaging surface of image sensor 16 and other macro lenses. During image capture operations, light from a scene may be focused onto image sensor 16 by lenses 14. Image sensor 16 may include circuitry for converting analog pixel image signals into corresponding digital image data to be provided to storage and processing circuitry 18. If desired, camera module 12 may be provided with an array of lenses 14 and an array of corresponding image sensors 16.

Storage and processing circuitry 18 may include one or more integrated circuits (e.g., image processing circuits, microprocessors, storage devices such as random-access memory and non-volatile memory, etc.) and may be implemented using components that are separate from the camera module and/or that form part of the camera module (e.g., circuits that form part of an integrated circuit that includes image sensors 16 or an integrated circuit within the module that is associated with image sensors 16). When storage and processing circuitry 18 is included on different integrated circuits (e.g., chips or dies) than those of image sensors 16, the integrated circuits with circuitry 18 may be vertically stacked or packaged with respect to the integrated circuits with image sensors 16. Image data that has been captured by camera module 12 may be processed and stored using processing circuitry 18 (e.g., using an image processing engine on processing circuitry 18, using an imaging mode selection engine on processing circuitry 18, etc.). The processed image data may, if desired, be provided to external equipment (e.g., a computer, external display, or other device) using wired and/or wireless communications paths coupled to processing circuitry 18.

As shown in FIG. 2, image sensor 16 may include a pixel array 20 containing image sensor pixels 22 (sometimes referred to herein as image pixels or pixels) arranged in rows and columns and control and processing circuitry 24 (sometimes referred to herein as control circuitry). Array 20 may contain, for example, hundreds or thousands of rows and columns of image sensor pixels 22. Control circuitry 24 may be coupled to row control circuitry 26 (sometimes referred to herein as row driver circuitry or row decoder circuitry) and image readout circuitry 28 (sometimes referred to as column control circuitry, column readout circuitry, readout circuitry, or column decoder circuitry). Row control circuitry 26 may receive row addresses from control circuitry 24 and supply corresponding row control signals such as reset, row-select, charge transfer, dual conversion gain, and readout control signals to pixels 22 over row control paths 30. One or more conductive lines such as column lines 32 may be coupled to each column of pixels 22 in array 20. Column lines 32 may be used for reading out image signals from pixels 22 and for supplying bias signals (e.g., bias currents or bias voltages) to pixels 22 (to read out the image signals). If desired, during pixel readout operations, a pixel row in array 20 may be selected using row control circuitry 26 and image signals generated by image pixels 22 in that pixel row may be read out along column lines 32.

Readout circuitry 28 may receive image signals (e.g., analog pixel values generated by pixels 22) over column lines 32. Readout circuitry 28 may include sample-and-hold circuitry for sampling and temporarily storing image signals read out from array 20, amplifier circuitry or a multiplier circuit, analog-to-digital conversion (ADC) circuitry, bias circuitry, column memory, latch circuitry for selectively enabling or disabling the column circuitry, or other circuitry that is coupled to one or more columns of pixels in array 20 for operating pixels 22 and/or for reading out image signals from pixels 22. ADC circuitry in readout circuitry 28 may convert analog pixel values received from array 20 into corresponding digital pixel values (sometimes referred to as digital image data or digital pixel data). Readout circuitry 28 may supply digital pixel data to control and processing circuitry 24 and/or processor 18 (FIG. 1) for pixels in one or more pixel columns.

Pixel array 20 may be provided with a filter array having multiple (color) filter elements (each corresponding to a respective pixel) which allows a single image sensor to sample light of different colors or sets of wavelengths. As an example, image sensor pixels such as the image pixels in array 20 may be provided with a color filter array having red, green, and blue filter elements, which allows a single image sensor to sample red, green, and blue (RGB) light using corresponding red, green, and blue image sensor pixels arranged in a Bayer mosaic pattern.

In another suitable example, the green pixels in a Bayer pattern may be replaced by broadband image pixels having broadband color filter elements (e.g., clear color filter elements, yellow color filter elements, etc.). In yet another example, one of the green pixels in a Bayer pattern may be replaced by infrared (IR) image pixels formed under IR color filter elements and/or the remaining red, green, and blue image pixels may also be sensitive to IR light (e.g., may be formed under filter elements that pass IR light in addition to light of their respective colors). These examples are merely illustrative and, in general, filter elements of any desired color and/or wavelength and in any desired pattern may be formed over any desired number of image pixels 22. If desired, one or more filter elements over array 20 may be omitted.

A separate microlens may be formed over each image pixel 22 (e.g., with light or color filter elements interposed between the microlenses and image pixels 22). The microlenses may form an array of microlenses that overlap the array of light filter elements and image pixel array 20. Each microlens may focus light from an imaging system lens onto a corresponding image pixel 22, or multiple image pixels 22 if desired.

Image pixels 22 may be formed in a semiconductor substrate using complementary metal-oxide-semiconductor (CMOS) technology, charge-coupled device (CCD) technology, both CMOS and CCD technologies, or any other suitable photosensitive device technology. Image pixels 22 may be frontside illumination (FSI) image pixels or backside illumination (BSI) image pixels. If desired, image sensor 16 may include an integrated circuit package or other structure in which multiple integrated circuit substrate layers or chips are vertically stacked with respect to each other. In this scenario, one or more of circuitry 24, 26, and 28 may be vertically stacked above or below array 20 within image sensor 16. If desired, lines 32 and 30 may be formed from vertical conductive via structures (e.g., through-silicon vias, through-oxide vias, etc.) and/or horizontal interconnect lines.

In some configurations, image pixels 22 may include more than one photosensitive elements for generating charge in response to image light. As an example, each image pixel 22 may include two photosensitive elements. The two photosensitive elements may be of different sizes with an outer (larger) photosensitive element surrounding an inner (smaller) photosensitive element. This is merely illustrative. If desired, the two photosensitive elements in each image pixel 22 may be arranged in any suitable manner. If desired, each image pixel 22 may include any suitable number of photosensitive elements.

FIG. 3 is a diagram of an illustrative image pixel 22 having two photosensitive elements. As shown in FIG. 3, pixel 22 may include multiple photosensitive elements or photosensitive regions such as photodiodes 40 and 42. As an example, one or both of photodiodes 40 and 42 may be photodiodes of a partially-pinned fully-depleted type. If desired, one or both photodiodes 40 and 42 may be any other suitable types of photodiodes.

Incoming light may be received by photodiodes 40 and 42. Photodiodes 40 and 42 may generate respective charges (e.g., electrons) in response to receiving corresponding impinging photons. The amount of charge that is collected by each of photodiodes 40 and 42 depends on the intensity of the corresponding impinging light and the exposure duration (or integration time) for photodiodes 40 and 42.

Respective first terminals of photodiodes 40 and 42 may be coupled to voltage source 39 (e.g., a ground voltage terminal, a power supply voltage terminal, etc.) that is configured to provide any suitable voltage. Respective second terminals of photodiodes 40 and 42 may be coupled to charge storage region 48 (sometimes referred to herein as a floating diffusion region) via corresponding transistors 44 and 46. Floating diffusion region 48 may have a capacitance C_{FD}. As an example, floating diffusion region 48 may be a doped semiconductor region (e.g., a region in a silicon substrate that is doped by ion implantation, impurity diffusion, or other doping process).

Control signal TX1 may control transistor 44 to transfer charge generated at photodiode 40 to floating diffusion region 48. Control signal TX2 may control transistor 46 to electrically connect photodiode 42 to floating diffusion region 48. Reset transistor 62 controlled by control signal RST (in combination with transistor 60 controlled by control signal DCG) may couple voltage source 70 to floating diffusion region 48. As an example, voltage source 70 may be a power supply voltage terminal supplying a positive power supply voltage. If desired, voltage source 70 may instead provide a ground voltage terminal or other terminal supplying any suitable voltage. Transistors 60 and 62 may be turned on to reset floating diffusion region 48 to a reset voltage (e.g., the voltage at supply terminal 70).

The voltage levels stored at floating diffusion region 48 (e.g., the charge received from photodiodes 40 and 42, the reset voltage) may be read out using charge readout circuitry in pixel 22. The charge readout circuitry may include source follower transistor 72 and row select transistor 74. The charge (corresponding a voltage level) stored at floating diffusion region 48 may correspond to a reset level signal, a reference level signal, or an image level signal. Transistor 72 may couple voltage source 70 to transistor 74. Row select transistor 74 may have a gate terminal that is controlled by a row select signal (e.g., control signal RS). When the row select signal is asserted, transistor 74 may be turned on and a pixel output signal (e.g. an output signal having a magnitude that is proportional to the voltage (associated with the charge) at floating diffusion region 48) may be passed onto pixel output path 76 (e.g., corresponding to column line 32 in FIGS. 2 and 3).

To selectively extend the storage capacity of floating diffusion region 48 and generate signals associated with different conversion gains, capacitor 64 (sometimes referred to herein as a charge storage structure) may be coupled to floating diffusion region 48 using dual conversion gain transistor 60. To further extend the dynamic range of pixel 22 while improving the signal-to-noise ratio of the image signals generated by pixel 22, pixel 22 may include capacitor 66 (sometimes referred to herein as a charge storage structure). Capacitor 66 may be coupled to the second terminal of photodiode 42 (e.g., the same terminal of photodiode 42 to which transistor 46 is coupled).

Capacitors 64 and 66 may each be formed from any suitable type of capacitive structures such as MiM (metal-insulator-metal) capacitor structures, PoD (poly-silicon on diffusion) or MOS (metal-oxide-semiconductor) capacitor structures, PiP (poly-silicon insulator poly-silicon) capacitor structures, any combination of these capacitor structures, or any other suitable types of capacitive structures. As an example, capacitor 64 may be formed from PiP capacitor structures formed over (e.g., that overlaps with) PoD capacitor structures. As an example, capacitor 66 may be formed from MiM capacitor structures.

In the example of FIG. 3, capacitor 66 may have a first (storage) terminal that is directly connected to a terminal of photodiode 42 (e.g., the second terminal of photodiode 42). Capacitor 66 may have a second (reference) terminal that is directedly connected to a voltage source (e.g., voltage source 68). Voltage source 68 may supply a voltage level CAPREF to the second terminal of capacitor 66. Voltage level CAPREF may be a fixed reference voltage (e.g., a voltage level fixed a ground voltage level, a voltage level fixed at a power supply voltage level) or a variable reference voltage (e.g., a voltage level that varies based on the operation of pixel 22, a voltage level that is at a first (ground) voltage level at a first given time and at a second (power supply or other reference) voltage level at a second time). A switchable or variable reference voltage may allow for a higher voltage to be supplied to capacitors 64 and/or 66 during shutter (or reset) operations and readout operations, and a lower voltage to be supplied to capacitors 64 and/or 66 during signal integration operations. This (e.g., the reduced voltage during integration operations) can reduce the dark current generation (e.g., reduces noise from dark current non-uniformity) during integration operations.

If desired, capacitor 64 may be coupled to the same voltage source 68 (e.g., a same or different voltage supply structure that supplies the same reference voltage level CAPREF). Capacitor 64 may have a first (storage) terminal that is directly connected to transistor 60 and may have a second (reference) terminal that is directly connected to voltage source 68. Alternatively, capacitors 64 and 66 may be connected to voltage sources supplying different voltage levels.

Capacitors 64 and 66 may be referred to herein sometimes as low gain capacitors. In the example of FIG. 3, capacitor 66 may be directedly connected to photodiode 42 (e.g., without any interposing transistors). This direct connection may be possible because charge generated by photodiode 42 may be read out only in a low (conversion) gain mode (e.g., photodiode 42 may be used to generate a low conversion gain signal and not a high conversion gain signal.). Capacitor 64 may be electrically connected to floating diffusion region 48 to read out charge generated from either photodiode 40 or photodiode 42 in a low (conversion) gain mode, and may be electrically disconnected from floating diffusion region 48 to read out charge generated from photodiode 40 in a high (conversion) gain mode. In other words, capacitor 66 may be dedicated to store charge for a low gain signal generated using photodiode 42. Capacitor 64 may be configured to store charge for a low gain signal generated by photodiode 40 or a low gain signal generated by photodiode 42.

The configuration of pixel 22 in FIG. 3 is merely illustrative. If desired, pixel 22 may have any circuitry in addition to or instead of the circuitry shown in FIG. 3 (e.g., the charge storage regions, transistors, photosensitive elements, etc.). If desired, one or more portions of pixel 22 in FIG. 3 may be omitted. If desired, the elements shown in FIG. 3 may be coupled or connected in any suitable manner. If desired, the supply terminal coupled to transistor 62 may supply a different voltage than the voltage supplied by the supply terminal coupled to transistor 72.

As an example, in FIG. 3, transistor 46 may directly connect photodiode 42 to floating diffusion region 48. However, if desired, transistor 46 may indirectly connect photodiode 42 to floating diffusion region 48 (e.g., to achieve a desirable layout, to provide a desirable manufacturing process, to reduce noise, etc.). FIG. 4 is a diagram of an illustrative pixel 22 that includes a more indirect path between photodiode 42 and floating diffusion region 48 (when compared to that of pixel 22 in FIG. 3).

As shown in FIG. 4, transistor 46 may have a first source-drain terminal (i.e., either the source terminal or the drain terminal) that is coupled to photodiode 42 and may have a second source-drain terminal (i.e., the other one of the source terminal or the drain terminal) that is coupled to a node between transistors 60 and 62 (e.g., the same node to which the first terminal of capacitor 64 is coupled). In other words, transistors 60 and 62 may have respective source-drain terminals directed connected to each other, and both transistor 46 and capacitor 64 may have respective terminals that are directed to the common respective source-drain terminals of transistors 60 and 62. In this configuration, low gain capacitors 64 and 66 may serve similar functions as described in connection with FIG. 3 (e.g., to store charge for a low conversion gain mode of operation). Capacitor 66 may be dedicated to store charge for a low gain signal generated using photodiode 42. Capacitor 64 may be configured to store charge for a low gain signal generated by photodiode 40 or a low gain signal generated by photodiode 42.

As described in connection with FIG. 3, additional circuitry may be included in pixel 22 of FIG. 3. FIG. 5 is a diagram of an illustrative pixel having an additional transistor interposed between a photodiode (e.g., photodiode 42) and a floating diffusion region (e.g., floating diffusion region 48). As shown in FIG. 5, pixel 22 may include photodiode 42 and floating diffusion region 48. Pixel 22 of FIG. 5 may include transistor 46 that (directly) connects photodiode 42 to low gain capacitor 66. Pixel 22 of FIG. 5 may include additional transistor 67 (controlled by control signal TX3) that (directly) connects low gain capacitor 66 to floating diffusion region 48. In the configuration of FIG. 5, a separate transistor (e.g., transistor 67) may selectively control the connection between capacitor 66 and floating diffusion region 48 (e.g., consequently between capacitor 66 and a readout section of pixel 22). While the pixel configuration of FIG. 5 includes an additional transistor than that of FIG. 3, the additional transistor may provide additional control between the charge generation portion of pixel 22 (e.g., photodiode 42, capacitor 66, etc.) and the readout portion of pixel 22 (e.g., floating diffusion region 48, source follower transistor 72, etc.).

As an example, in FIG. 5, transistor 67 may directly connect capacitor 66 to floating diffusion region 48. If desired, transistor 67 may indirectly couple capacitor 66 to floating diffusion region 48 (e.g., to achieve desirable layout, to provide a desirable manufacturing process, to reduce noise, etc.). FIG. 6 is a diagram of an illustrative pixel 22 that includes a more indirect path between capacitor 66 and floating diffusion region 48 (when compared to that of pixel 22 in FIG. 5).

As shown in FIG. 6, transistor 67 may have a first source-drain terminal that is coupled to capacitor 66 and may have a second source-drain terminal that is coupled to a node between transistor 60 and 62 (e.g., the same node to which the first terminal of capacitor 64 is coupled). In other words, transistors 60 and 62 may have respective source-drain terminals directed connected to each other, and both transistor 67 and capacitor 64 may have respective terminals that are directed to the common respective source-drain terminals of transistor 60 and 62. In this configuration, low gain capacitors 64 and 66 may serve similar functions as described in connection with FIGS. 3-5 (e.g., to store charge for a low gain mode of operation). Capacitor 66 may be dedicated to store charge for a low gain signal generated using photodiode 42. Capacitor 64 may be dedicated to store charge for a low gain signal generated by photodiode 40 or a low gain signal generated by photodiode 42.

Respective pixels 22 in FIGS. 3-6 are merely illustrative. If desired, any suitable modifications may be made to these configurations of pixels 22. Additionally, elements in FIGS. 3-6 having similar reference numerals may have similar configurations, may serve similar purposes, may operate in similarly manners, etc. Repetitive descriptions of these shared elements are omitted in order not to unnecessarily obscure the respective embodiments of the corresponding figures.

FIG. 7 is a diagram of illustrative inner and outer photosensitive elements in a pixel (in a surface or top-down view of the pixel). In particular, pixel 22 may include inner photosensitive element 52 and outer photosensitive elements 54 and 56 (sometimes referred to herein the three sub-pixels of pixel 22).

As shown in FIG. 7, inner photosensitive element 52 of pixel 22 may include light collecting area 51 (sometimes referred to herein as a light collecting region) and may include isolation regions that isolate light collecting area 52 from other pixel elements (e.g., other photosensitive elements, transistors, signal paths, etc.). The isolation regions of inner photosensitive element 52 may define a (surface or top-view) shape of light collecting area 51. In the example of FIG. 7, light collecting area 51 may have an octagonal shape and inner photosensitive element 52 may have a rectangular shape. These shapes are merely illustrative. If desired, inner photosensitive element 52 and light collecting area 51 may each have a circular shape, a rectangular shape, a polygonal shape, an irregular shape, or any other suitable shapes.

Outer photosensitive elements 54 and 56 of pixel 22 may include respective light collecting areas 53 and 55 (sometimes referred to herein as light collecting regions) and may include respective isolation regions that isolate the corresponding light collecting areas from other pixel elements (e.g., other photosensitive elements, transistors, signals paths, light collecting areas, etc.). The isolation region of (left) outer photosensitive element 54 may define a (surface or top-view) shape of light collecting area 53, and similarly, the isolation region of (right) outer photosensitive element 56 may defined a (surface or top-view) shape of light collecting area 55. These shapes are merely illustrative. If desired, outer photosensitive element 54, light collecting area 53, outer photosensitive element 56, and light collecting area 55 may each have a circular shape, a rectangular shape, a polygonal shape, an irregular shape, or any other suitable shapes.

Pixel 22 may also include isolation region 58 that separates inner photosensitive element 52, left outer photosensitive element 54, and right outer photosensitive element 56 from one another. Isolation region 58 may include different types of isolation structures such as trench isolation structures, doped semiconductor regions metallic barrier structures, or any other suitable isolation structures. As a particular example, isolation region 58 may be formed from (backside) deep trench isolation structures and/or shallow trench isolations structures. Isolation region 58 may include one or more first portions that separate left outer photosensitive element 54 from right outer photosensitive element 56. Isolation region 58 may include one or more second portions that separate inner photosensitive element 52 from the outer photosensitive elements 54 and 56.

The placement and features (e.g., shape or outline) of isolation region 58 is merely illustrative. If desired, one or more of portions of isolation region 58 may be omitted. If desired, additional isolation regions may be included in pixel 22. As an example, adjacent pixels 22 may be separated by additional isolation structures (e.g., a grid of isolation regions may separate pixels 22 in array 20 from one another).

In the example of FIG. 7, outer photosensitive elements 54 and 56 may surround photosensitive element 52 except for the gaps between photosensitive elements 54 and 56 associated with isolation region 58. In other words, inner photosensitive element 52 may be nested within and may be fully laterally surrounded by outer photosensitive elements 54 and 56, and the portions of isolation region 58 between photosensitive elements 54 and 56.

If desired, light collecting areas 53 and 55 may be configured to operate collectively for a single outer photosensitive element (e.g., a single outer photosensitive element represented by the combination of left and right outer photosensitive elements). As an example, light collecting areas 53 and 55 may form a continuous light collecting area (e.g., the portion of isolation region 58 and other isolation regions between light collecting areas 53 and 55 may be omitted to form the single continuous light collecting area). As another example, light collecting areas 53 and 55 may be connected to a common node or charge sharing region but may not be directly connected to each other in the layout of FIG. 7 (e.g., isolation regions such as isolation region 58 may still separate portions of light collecting areas 53 and 55 from each other).

In some configurations, some portions of pixels 22 in FIGS. 3-6 may be formed from the type of pixel configuration shown in FIG. 7. In particular, inner photosensitive element 52 may form photosensitive elements 42 in FIGS. 3-6, and one or both of outer photosensitive elements 54 and 56 (or a combined outer photosensitive element formed from regions 54 and 56 as a combination with a single continuous light collecting area or with separate light collecting areas) may form photosensitive elements 40 in FIGS. 3-6. Therefore, the inner photosensitive element (e.g., photodiode 42) may be operable to collect charge useable to generate a low (conversion) gain signal. The outer photosensitive element (e.g., photodiode 40) surrounding the inner photosensitive element may be operable to collect charge useable to generate both a low (conversion) gain signal and a high (conversion) gain signal.

The configuration and elements shown in FIG. 7 (e.g., photosensitive elements 52, 54, and 56, isolation region 58, etc.) are merely illustrative. Other elements in pixel 22 are omitted from FIG. 7 in order to not obscure the embodiments of FIG. 7. However, these omitted elements may be coupled to, be electrically connected to, overlap, or relate to the elements shown in FIG. 7 in any suitable manner. As an example, (MiM) capacitor structures (e.g., capacitors 66 in FIGS. 3-6) may overlap at least parts of one or more of photosensitive elements 52, 54, and 56 (e.g., may overlap substantially with the entire pixel area). If desired, other capacitor structures (e.g., capacitors 64 in FIGS. 3-6) may overlap only some parts of some of photosensitive elements 52, 54, and 56. Transistors, voltage rails (e.g., voltage sources), or other structures in pixel 22 may also be coupled to and/or overlap photosensitive elements 52, 54, and 56.

In some configurations, pixel 22 may include separate photosensitive regions, where one photosensitive region is not surrounded by or nested within another photosensitive region. As an example, pixel 22 may include a first photosensitive regions having a larger light collecting area than a light collecting area of a second photosensitive regions in pixel 22. As an example, the first photosensitive region may be at a corner or a side of a pixel 22 and the second photosensitive region may take up substantially the remaining area on pixel 22. In the scenarios where the first photosensitive region is formed at a corner or only a portion of a side of pixel 22, the second photosensitive region may still surround the first photosensitive region (e.g., at least partially surround two or three sides of the first photosensitive region).

FIG. 8 is a diagram of an illustrative photosensitive element formed in a pixel. As an example, FIG. 8 may be a cross-sectional view of a portion of one or more of pixels 22 shown in FIGS. 3-7. As shown in FIG. 8, a (semiconductor) substrate may include a (p-type) doped region 110. Field oxide (e.g., silicon oxide) region 108 may be formed within (or over) doped region 110 (e.g., at the surface of the substrate). Field oxide region 108 may isolate pixel circuitry from other nearby circuitry (e.g., pixel circuitry from other pixels, other pixel circuitry from the same pixel, etc.).

In the example of FIG. 8, the photosensitive element (for pixel 22) may be formed from a (p-type) implant region 102 (e.g., at the surface of the substrate) and a (n-type) implant region 104 (e.g., having a portion below implant region 102. A depletion region 112 may be formed below implant region 104. One of the two heavily (n+-type) doped regions 106 may be formed within implant region 104 at the surface of the substrate. This heavily doped region 106 may be separates from to implant region 102 on the left by a portion of implant region 104 and may be adjacent to (e.g., in contact with) doped region 110 on the right. A metal contact structure may form an electrical connection to heavily doped region 106 and may thereby connect to the photosensitive element (e.g., at (n-type) implant region 104). Implant region 102 may span (substantially) the entire distance between field oxide region 108 and heavily doped region 106 and may also span (substantially the entire width of the photosensitive element (e.g., at the substrate surface). The configuration of the photosensitive element in FIG. 8 may be used to form a partially-pinned (substantially) fully-depleted photodiode, which may be used to form photodiodes 42 in FIGS. 3-6, as an example. If desired, photodiodes 40 in FIGS. 3-6 may be formed from the partially-pinned fully-depleted photodiode in FIG. 8.

As shown in FIG. 8, a transistor may be coupled to the photosensitive element. The transistor may include a gate structure 107 formed over a portion of doped region 110 at the substrate surface (e.g., a channel region formed from doped region 110). The transistor may also include source-drain terminals formed from heavily doped region (or wells) 106 on both sides of the channel region.

In the buried photodiode region configuration shown in FIG. 8, there may be lower dark current generation from the photosensitive element or photodiode. This is merely illustrative. If desired, photosensitive elements 40 and 42 for pixel 22 in FIGS. 3-6) may be formed using any other suitable type of photosensitive element.

FIG. 9 is a timing diagram for operating an image sensor (e.g., an image pixel in the image sensor) which includes two low gain capacitors per pixel. As an example, the timing diagram of FIG. 9 may be used to operate an image sensor 16 having image pixels 22 of the types shown in FIG. 3 or 4.

As shown in FIG. 9, the timing diagram may include a shutter or reset time period, a charge integration or charge accumulation time period, and (charge) readout time period. In the example of FIG. 9, one or more of these time periods may overlap one another. During the shutter time period, control circuitry, such as row control circuitry 26 and/or control circuitry 24 in FIG. 2, may assert control signals RS (e.g., for controlling transistor 74 in FIG. 3), TX1 (e.g., for controlling transistor 44 in FIG. 3), TX2 (e.g., for controlling transistor 46 in FIG. 3), and RST (e.g., for controlling transistor 62 in FIG. 3), DCG (e.g., for controlling transistor 60 in FIG. 3) to reset charge integrating and charge storage elements or structures in pixel 22 and prepare pixel 22 for signal integration and readout. During the shutter time period, variable voltage signal CAPREF (e.g., for providing a reference voltage to respective second terminals of capacitors 64 and 66 in FIG. 3) may be at a high voltage level (e.g., at a power supply voltage level, at a voltage level between the power supply voltage level and a ground voltage level, etc.). These assertions and high voltage levels are shown in FIG. 9 as assertions A1-A6.

Following the shutter time period, a (charge or signal) integration time period may begin. During the signal integration period, photodiodes 40 and 42 may both generate or integrate charge in response to incident light. As described herein as an illustrative example, photodiode 40 may be formed as an outer photodiode that surrounds an inner photodiode that forms photodiode 42. In such a configuration, the light-sensitive or light collecting area of photodiode 42 may be smaller than that of photodiode 40.

During the charge integration time period, the control circuitry may partially assert control signal TX1 periodically (e.g., corresponding to assertions B1, B2, . . . , Bn) any suitable number of times. During each of these partial assertions, control signal TX1 may control transistor 44 in FIG. 3 to set a voltage barrier that allows only charge above a certain voltage threshold to pass from photodiode 40 to floating diffusion region 48. The passed charge above the voltage barrier may be referred to herein as overflow charge or an overflow portion of the charge generated by photodiode 40. The voltage barrier may be set by the voltage level supplied to the gate terminal of transistor 44 using control signal TX1 during the partial assertion. These partial assertion operations may be associated with generating the overflow charge and leaving a remaining portion of the charge generated by photodiode 40 at photodiode 40.

If desired, other assertions for control signal TX1 (e.g., assertions not for generating overflow charge, assertions during shutter operations, some assertions during readout operations) may be full assertions at a voltage level higher in magnitude than the voltage level used for partial assertions. When control signal TX1 is partially asserted, control circuitry may also simultaneously (and partially) assert control signal DCG to extend the storage capacity of floating diffusion region 48 by connecting floating diffusion region 48 to capacitor 64. As such, the overflow charge may be stored capacitor 64 (and temporarily in floating diffusion region 48). During the charge integration time period, variable voltage signal CAPREF may supply a low voltage to the respective reference (second) terminals of capacitors 64 and 66 (e.g., a voltage lower than the voltage level supplied during the shutter time period, a ground voltage level, etc.).

Before the start of readout operations, the control circuitry may partially assert control signal TX1 a final time (corresponding to assertion D) and simultaneously fully assert control signal DCG to transfer the final overflow portion of charge to capacitor 64 (corresponding to assertion E). This final set of assertions may ensure all of the accumulated or combined overflow charge is stored at capacitor 64. During this process, reference voltage CAPREF provided to the reference terminal of capacitor 64 (and optionally capacitor 66) may shift higher in voltage to the high voltage level. The reference voltage CAPREF may remain at the high voltage during the readout operations (e.g., corresponding to assertion S).

Throughout signal readout operations, the control circuitry may assert control signal RS (e.g., corresponding to assertion L) to pass signals being read out onto the pixel output path (e.g., path 76 in FIG. 3). During the signal readout operations, control circuitry (e.g., control circuitry 24, 26, and/or 28 in FIG. 2) may assert one or more control signals (collectively shown as signal SH if there are multiple control signals) corresponding to the use of sample-and-hold circuitry (e.g., in column circuitry 28 in FIG. 2).

As shown in FIG. 9, the control circuitry may first assert signal SH to read out a reset level signal based on a reset voltage level at floating diffusion region 48 (e.g., assertion J). Thereafter, the control circuitry may assert control signal TX1 (e.g., assertion K) to transfer the charge generated and stored at photodiode 40 (e.g., the portion of the charge remaining after transferring the overflow charge using assertion D) to floating diffusion region 48. Optionally, the control circuitry may partially assert control signal DCG to transfer a suitable amount of the remaining charge stored at photodiode 40 to floating diffusion region 48 (e.g., using assertion E′). The control circuitry may perform sample and hold operations (e.g., readout operations) on the remaining portion of the charge generated by photodiode 40 (less any charge portion transferred using assertion E′) using assertion M. This readout operation may read out a high conversion gain (HCG) image signal (sometimes referred to herein as an “E1” signal) that corresponds to the remaining charge portion generated at photodiode 40. This high conversion gain image signal may be useable for a low light image environment (e.g., for the low light intensity portion of the dynamic range). This readout operation (in combination with the previous reset level signal readout) may be a correlated double sampling readout.

Thereafter, the control circuitry may assert control signals TX1 (e.g., using assertion D′) to transfer any charge generated by photodiode 40 after assertion K to floating diffusion region 48 (or to transfer charge that was left in photodiode 42 because of insufficient available voltage swing at floating diffusion region 48). Concurrently or separately, control signal DCG may be asserted by the control circuitry to electrically connect capacitor 64 to floating diffusion region 48. The control circuitry may continue to assert control signal DCG through the rest of the readout operations (e.g., using assertion O). The two transferred charges may be combined at floating diffusion region 48. This combined charge may be read out using assertion F (associated with signal SH). This readout operation may read out a low conversion gain (LCG) image signal (sometimes referred to herein as an “E2” signal) that corresponds to the combined charge (e.g., overflow charge and newly integrated charge) transferred to floating diffusion region 48 using assertions D′ and O. This low conversion gain (LCG) image signal may be referred to sometimes as an overflow low conversion gain image signal for photodiode 40 and may be useable for a mid-light image environment (e.g., for the mid-light intensity portion of the dynamic range).

Following assertion F, the control circuitry may assert control signal RST (e.g., using assertion G) and keep control signal DCG asserted (e.g., using assertion O) to reset floating diffusion region 48 and capacitor 64 (e.g., the storage terminal of capacitor 66) to a reset level voltage (supplied by voltage source 70). Subsequently, this reset voltage level stored at the floating diffusion region 48 may be read out as a second reset level signal using assertion H (associated with signal SH). The readout operations for the overflow LCG image signal for photodiode 40 (in combination with this second reset level signal readout) may be a double sampling readout operation.

Following the readout operations for charge generated by photodiode 40, charge generated by photodiode 42 may be read out. As shown in FIG. 9, the control circuitry may assert control signal TX2 to transfer all of the charge generated by photodiode 42 to floating diffusion region 48 (e.g., using assertion P). The charge generated by photodiode 42 and transferred to floating diffusion region 48 may be read out using assertion Q. This readout operation may read out a second low conversion gain (LCG) image signal (sometimes referred to herein as an “E3” signal) that corresponds to the total charge generated by photodiode 42 and transferred to floating diffusion region 48 using assertion P. This second low conversion gain (LCG) image signal may be referred to as a low conversion gain image signal for photodiode 42 and may be useable for a high light image environment (e.g., for the high light intensity portion of the dynamic range).

Thereafter, the control circuitry may assert control signal RST (in combination with control signal DCG) to reset floating diffusion region 48 and capacitor 64 (e.g., the storage terminal of capacitor 64) to the reset level voltage (supplied by voltage source 70). Control signal TX2 may remain asserted using assertion P (while control signals RST and DCG are asserted) such that photodiode 42 and capacitor 66 may also be reset to the reset level voltage (supplied by voltage source 70). Subsequently, this reset voltage level stored at the floating diffusion region 48 may be read out as a third reset level signal using assertion T (associated with signal SH). The readout operations for the LCG image signal for photodiode 42 (in combination with this third reset level signal readout) may be a correlated readout operation.

As shown in FIG. 9, the integration times for generating the E1, E2, and E3 image signals may be different. In particular, the E1 signal may be generated based on the remaining charge portion of photodiode 40 generated during integration time period Tint. The E2 signal may be generated based on the overflow charge portion of photodiode 40 generated during integration time period Tint and based on the total charge generated by photodiode 40 during integration time period “LCG Tint” (extending from assertion K to assertion D′). The E3 signal may be generated based on the total charge generated by photodiode 42 during integration time period “PD2 Tint”. Time period “PD2 Tint” may begin at the same time as the beginning of time period Tint and may end at (the end of) assertion Q. Because the integration time period “PD2 Tint” is long, capacitor 66 coupled to photodiode 42 may help extend the storage capacity of photodiode 42 to capture all of the generated charge.

The timing diagram of FIG. 9 is merely illustrative. If desired, pixels 22 in FIGS. 3 and 4 (and/or in the other figures) may be operable in any suitable manner. As a particular example, FIG. 10 is a timing diagram for operating pixels 22 in FIGS. 3 and 4 such that the E2 signal is read out before the E1 signal.

As shown in FIG. 10, the control circuitry may control signals RS, TX1, TX2, RST, DCG, and CAPREF in a similar manner as shown in FIG. 9 during the shutter time period and during integration time period Tint (e.g., for assertions A1-A6. B1-Bn, C1-Cn).

In contrast to FIG. 9, the E2 or overflow LCG image signal may be read out first. In particular, assertion D and E may be used to transfer the accumulated overflow charge from photodiode 42 and capacitor 64 to floating diffusion region 48. This accumulated charge may be read out first as the overflow LCG image signal (e.g., using assertion F). Assertion G may be used to reset floating diffusion region 48 and capacitor 64. Thereafter, the reset level voltage at floating diffusion region 48 may be read out using assertion H as a first reset level signal.

After the E2 or overflow LCG image signal is read out, the E1 or HCG image signal may be read out. In particular, assertions I and E may be used to reset floating diffusion region 48 once again. Thereafter, this reset level voltage at floating diffusion region 48 may be read out using assertion J as a second reset level signal. Assertion K may be used to transfer the remaining portion of the charge generated by photodiode 40 during time period Tint (or the charge left behind after the first charge transfer operation) and also any additional charge generated by photodiode 40 between assertion D and K. This combined charge may be read out second as the HCG image signal. The readout for the E3 signal associated with charge generated by photodiode 42 may be similar to that of FIG. 9.

The timing diagrams of FIGS. 9 and 10 are merely illustrative. If desired, these timing diagrams may be modified in any suitable manner. As an example, the timing diagrams of FIGS. 9 and 10 may be adapted to incorporate control signal TX3 to operate an image sensor 16 having image pixels 22 of the types shown in FIGS. 5 and 6. In particular, control signal TX3 (along with control signal TX2) may be asserted to transfer charge from photodiode 42 to floating diffusion region 48 during the charge readout operations for photodiode 42. Otherwise, the other elements of the timing diagrams of FIGS. 9 and 10 may still be applicable to the image pixels 22 of the type shown in FIGS. 5 and 6.

As mentioned herein, the configuration of pixel 22 in FIG. 3 is merely illustrative. If desired additional elements may be included in pixel 22. As an example, FIG. 11 is a diagram of an illustrative pixel 22 having an additional transistor (e.g., anti-blooming transistor 37 coupled to photodiode 40) relative to the configuration of pixel 22 in FIG. 3. In particular, transistor 37 may receive control signal AB and may (selectively) couple photodiode 40 to voltage source 70. If desired, transistor 37 may be similarly included in any of the configurations of pixel 22 shown in FIGS. 4-6.

As another example, FIG. 12 is a diagram of an illustrative pixel 22 has a reset path for floating diffusion region 48 that is separate from a dual conversion gain path for floating diffusion region 48. In particular, reset transistor 62 may couple floating diffusion region 48 directly to voltage source 70 and dual conversion gain transistor 60 may couple only capacitor 64 (and not a reset transistor as FIG. 11) to floating diffusion region 48. As an illustrative configuration, voltage source 68 may be the same as voltage source 70 (e.g., voltage source 68 may supply the same voltage as the voltage supplied by voltage source 70). If desired, this parallel configuration for transistor 62 and transistor 60 may similarly be included in any of the configurations of pixel 22 as shown in FIGS. 4-6.

By using the pixels and timing diagrams described in connection with FIGS. 3-12, an image sensor or imaging system may be configured to generated image signals with a high dynamic range. In particular, the addition of capacitor 66 may extend the storage capacity of photodiode 42 (e.g., may provide a direct low gain capacitor for photodiode 42). An outer photodiode 40 may be used to generate an HCG image signal for a low light portion of the dynamic range and an overflow LCG image signal for a mid-light portion of the dynamic range. An inner photodiode 42 (with the help of capacitor 66) may be used to generate an LCG image signal for a high light portion of the dynamic range.

Various embodiments have been described illustrating systems and methods generating high dynamic range images.

As an example, an image sensor pixel may include a first photosensitive element, a second photosensitive element, a floating diffusion region coupled to the first and second photosensitive elements, a first charge storage structure coupled to the floating diffusion region, and a second charge storage structure coupled directly to the second photosensitive element. The second charge storage structure may have first and second terminals, the second photosensitive element may have first and second terminals, and the second terminal of the second charge storage structure may be electrically connected to the second terminal of the second photosensitive element. The first terminal of the charge storage structure may be coupled to a first voltage source and the first terminal of the second photosensitive element is coupled to a second voltage source.

The image sensor pixel may further include a first transistor that couples the first photosensitive element to the floating diffusion region, a second transistor that couples the second photosensitive element to the floating diffusion region, a third transistor that couples the first charge storage structure to the floating diffusion region and couples the second photosensitive element to the floating diffusion, a fourth transistor that, in combination with the third transistor, couples a third voltage source to the floating diffusion region. The image sensor pixel may further include charge readout circuitry coupled to the floating diffusion region. The first photosensitive element may surround the second photosensitive element, and the first and second photosensitive regions may include first and second separate light collecting areas, respectively. The second photosensitive element may include a partially-pinned fully-depleted photodiode, and the second charge storage structure may include a metal-insulator-metal capacitor structure.

As another example, an image sensor may include an array of image pixels. An image pixel in the array may include a first photodiode, a second photodiode nested within the first photodiode, a floating diffusion region, a first capacitor coupled to the floating diffusion region, and a second capacitor coupled to the second photodiode and coupled to the floating diffusion region. The image pixel may further include a first transistor that directly connects the second photodiode to the second capacitor, a second transistor that directly connects the first photodiode to the floating diffusion region, a third transistor that directly connects the first capacitor to the floating diffusion region, a fourth transistor that, in combination with the third transistor, directly connects the floating diffusion region to a voltage source, and a fifth transistor that directly connects the second capacitor to the floating diffusion region. If desired, the third and fifth transistors, in combination, may directly connect the second capacitor to the floating diffusion region.

As yet another example, an image sensor may include an array of image pixels. An image pixel in the array may include a first photodiode configured to generate a first charge, a second photodiode surrounded by the first photodiode and configured to generate a second charge, and a floating diffusion region coupled to the first and second photodiodes. The image sensor may further include control circuitry operable to generate control signals that control the image pixel to generate a first low conversion gain signal based on an overflow portion of the first charge, to generate a second low conversion gain signal based on an entirety of the second charge, and to generate a high conversion gain signal based on a remaining portion the first charge. The image pixel may further include a first charge storage structure configured to store the second charge generated by the second photodiode and a second charge storage structure configured to store the overflow portion of the first charge.

The foregoing is merely illustrative of the principles of this invention and various modifications can be made by those skilled in the art without departing from the scope and spirit of the invention. The foregoing embodiments may be implemented individually or in any combination.

What is claimed is:

1. An image sensor pixel comprising:
a first photosensitive element;
a second photosensitive element;
a floating diffusion region, wherein the first and second photosensitive elements are coupled to the floating diffusion region;
a first charge storage structure coupled to the floating diffusion region; and
a second charge storage structure coupled directly to the second photosensitive element.

2. The image sensor pixel defined in claim 1, wherein the second charge storage structure has first and second terminals and the second photosensitive element has first and second terminals, and wherein the second terminal of the second charge storage structure is electrically connected to the second terminal of the second photosensitive element.

3. The image sensor pixel defined in claim 2, wherein the first terminal of the charge storage structure is coupled to a first voltage source and the first terminal of the second photosensitive element is coupled to a second voltage source.

4. The image sensor pixel defined in claim 3, further comprising:
a first transistor that couples the first photosensitive element to the floating diffusion region; and
a second transistor that couples the second photosensitive element to the floating diffusion region.

5. The image sensor pixel defined in claim 4, further comprising:
a third transistor that couples the first charge storage structure to the floating diffusion region, wherein the third transistor couples the second photosensitive element to the floating diffusion.

6. The image sensor pixel defined in claim 5, further comprising:
a fourth transistor, wherein the fourth transistor and the third transistor couple a third voltage source to the floating diffusion region.

7. The image sensor pixel defined in claim 6, further comprising:
charge readout circuitry coupled to the floating diffusion region.

8. The image sensor pixel defined in claim 3, wherein the first photosensitive element at least partially surrounds the second photosensitive element, and the first and second photosensitive regions include first and second separate light collecting areas, respectively.

9. The image sensor pixel defined in claim 3, wherein the second photosensitive element comprises a partially-pinned fully-depleted photodiode.

10. The image sensor pixel defined in claim 1, wherein the second charge storage structure comprises a metal-insulator-metal capacitor structure.

11. An image sensor comprising:
an array of image pixels, an image pixel in the array comprising:
a first photodiode;
a second photodiode nested within the first photodiode;
a floating diffusion region;
a first capacitor coupled to the floating diffusion region; and
a second capacitor coupled to the second photodiode and coupled to the floating diffusion region.

12. The image sensor defined in claim 11, wherein the image pixel further comprises:
a first transistor that directly connects the second photodiode to the second capacitor; and
a second transistor that directly connects the first photodiode to the floating diffusion region.

13. The image sensor defined in claim 12, wherein the image pixel further comprises:
a third transistor that directly connects the first capacitor to the floating diffusion region; and
a fourth transistor, wherein the third and fourth transistors directly connect the floating diffusion region to a voltage source.

14. The image sensor defined in claim 13, wherein the image pixel further comprises:
a fifth transistor that directly connects the second capacitor to the floating diffusion region.

15. The image sensor defined in claim 13, wherein the image pixel further comprises:
a fifth transistor, wherein the third and fifth transistors directly connect the second capacitor to the floating diffusion region.

16. The image sensor defined in claim 11, wherein the second capacitor is directly connected to the photodiode.

17. The image sensor defined in claim 11, wherein the second photodiode comprises a partially-pinned and fully-depleted photodiode and the second capacitor comprises a metal-insulator-metal capacitor.

18. An image sensor comprising:
an array of image pixels, an image pixel in the array comprising:
a first photodiode configured to generate a first charge;
a second photodiode surrounded by the first photodiode and configured to generate a second charge; and
a floating diffusion region coupled to the first and second photodiodes; and
control circuitry operable to generate control signals that control the image pixel to generate a first low conversion gain signal based on the first charge, to generate a second low conversion gain signal based on the second charge, and to generate a high conversion gain signal based on the first charge.

19. The image sensor defined in claim 18, wherein the control circuitry is operable to generate the control signals that control the image pixel to generate a first low conversion gain signal based on an overflow portion of the first charge, to generate a second low conversion gain signal based on an entirety of the second charge, and to generate a high conversion gain signal based on a remaining portion the first charge.

20. The image sensor defined in claim 19, wherein the image pixel further comprises:
a first charge storage structure configured to store the second charge generated by the second photodiode; and
a second charge storage structure configured to store the overflow portion of the first charge.
